(19) United States
(12) Patent Application Publication
(10) Pub. No.: US 2012/0098418 A1
(43) Pub. Date: Apr. 26, 2012

(54) ORGANIC ELECTROLUMINESCENT ELEMENT AND METHOD FOR MANUFACTURING SAME

(76) Inventors: Yoichiro Yashiro, Osaka (JP); Koji Arai, Nara (JP); Akira Mori, Hyogo (JP); Yutaka Kuriya, Osaka (JP); Akira Okuda, Osaka (JP)

(21) Appl. No.: 13/377,311

(22) PCT Filed: Jun. 10, 2010
(86) PCT No.: PCT/JP10/03861

§ 371 Date: Dec. 9, 2011

(30) Foreign Application Priority Data
Jun. 11, 2009 (JP) 2009-140194

(51) Int. Cl. H05B 33/14; H01J 9/00

(52) U.S. Cl. 313/504; 445/58

(57) ABSTRACT

Disclosed is an organic electroluminescent element including: a substrate; and a positive electrode, an organic light-emitting layer, and a laminated negative electrode of two or more layers including a lower negative electrode and an upper negative electrode having different specific resistances from each other, the positive electrode, organic light-emitting layer, and laminated negative electrode sequentially provided on the substrate from the substrate side, and in the organic electroluminescent element, the lower negative electrode and the upper negative electrode include any one of ITO, IZO, GZO, and AZO as the main constituent, and the lower negative electrode is provided closer to the organic light-emitting layer than the upper negative electrode, and the lower negative electrode has a specific resistance higher than the specific resistance of the upper negative electrode adjacent to the lower negative electrode.

### BACKGROUND

1. Technical Field

This application claims the priority of Japanese Patent Application No. 2009-140194 filed in Japan on Jun. 11, 2009, the contents of which are hereby incorporated by reference.

The present invention relates to an organic electroluminescent element and a method for manufacturing the same.

2. Background Art

Conventional organic electroluminescent elements include a top-emission type element for extracting light from a top-side negative electrode, as shown in Japanese Patent Laid-Open Publication No. 2005-44799 (Patent Document 1). FIG. 7 is a cross-sectional view schematically illustrating the structure of a conventional organic electroluminescent element disclosed in Japanese Patent Laid-Open Publication No. 2005-44799 (Patent Document 1).

In FIG. 7, the conventional organic electroluminescent element has, on a base material 101, a stacked structure of a positive electrode 102, an organic light-emitting layer 103, an electron injecting layer 104, a conductive protective layer 105, and a negative electrode 106. In this organic electroluminescent element, voltage is applied between the positive electrode 102 and the negative electrode 106 to inject holes from the positive electrode 106 into the organic light-emitting layer 103, and injects electrons from the negative electrode 106 through the conductive protective layer 105 and the electron injecting layer 104 into the organic light-emitting layer 103. The two types of carriers are moved through the organic light-emitting layer 103, and recombined in the organic light-emitting layer 103 to generate excitons, and produce luminescence.

### PRIOR ART DOCUMENTS

### Patent Documents

### Patent Document 1: Japanese Patent Laid-Open Publication No. 2005-44799

### Patent Document 2: Japanese Patent Laid-Open Publication No. 2004-200141

### Patent Document 3: Japanese Patent Laid-Open Publication No. 10-294182

### SUMMARY OF THE INVENTION

However, the conventional structure described above has a problem of inability to achieve a sufficiently high luminous efficiency, when the specific resistance of a transparent electrode such as ITO, used for the negative electrode, is excessively low. When the specific resistance of the deposited film is excessively low in the deposition of the negative electrode, deposition damage to the organic light-emitting layer 103 is produced to cause a decrease in luminous efficiency.

An object of the present invention is to provide, mainly in view of the negative electrode structure of a top-emission type organic electroluminescent element, an organic electroluminescent element which achieves a high luminous efficiency, and a method for manufacturing the same.

An organic electroluminescent element according to the present invention includes: a substrate; and a positive electrode, an organic light-emitting layer, and a laminated negative electrode of two or more layers including a lower negative electrode and an upper negative electrode having different specific resistances from each other, the positive electrode, organic light-emitting layer, and laminated negative electrode sequentially provided on the substrate from the substrate side, wherein the lower negative electrode and of the upper negative electrode include any one of ITO, IZO, GZO, and AZO as a main constituent, and the lower negative electrode is provided closer to the organic light-emitting layer than the upper negative electrode, and the lower negative electrode has a specific resistance higher than the specific resistance of the upper negative electrode adjacent to the lower negative electrode.

This configuration can achieve a high luminous efficiency without adding a new material layer to a material layer of transparent conductive film such as ITO, mainly in terms of the negative electrode structure of a top-emission type organic electroluminescent element.

As described above, the organic electroluminescent element according to the present invention can achieve a high luminous efficiency without adding a new material layer to a material layer of transparent conductive film such as ITO, mainly in terms of the negative electrode structure of a top-emission type organic electroluminescent element. Furthermore, the method for manufacturing an electroluminescent element according to the present invention can manufacture an organic electroluminescent element which has a high luminous efficiency, without preparing any other new material in addition to materials for use in a conventional element structure.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a cross-sectional view schematically illustrating the structure of an organic electroluminescent element according to the first embodiment of the present invention;

FIG. 2 is a schematic view illustrating the structure of a sample used in a quantum efficiency measurement for an organic electroluminescent element according to the first embodiment of the present invention;

FIG. 3 is a schematic view illustrating the configuration of a measurement system used in a quantum efficiency measurement for an organic electroluminescent element according to the first embodiment of the present invention;

FIG. 4 is a graph showing the result of a quantum efficiency measurement for an organic electroluminescent element according to the first embodiment of the present invention, with the horizontal axis for the specific resistance of a laminated negative electrode and the vertical axis for a normalized internal quantum efficiency;

FIG. 5 is a diagram showing the relationship between an oxygen flow rate and the specific resistance of a negative electrode in the case of deposition according to the first embodiment of the present invention;

FIG. 6 is a cross-sectional view schematically illustrating the structure of an organic electroluminescent element according to the second embodiment of the present invention; and

FIG. 7 is a cross-sectional view schematically illustrating the structure of a conventional organic electroluminescent element.

### DETAILED DESCRIPTION OF THE PREFERRED EMBODIMENTS

Organic electroluminescent elements according to embodiments of the present invention will be described below with reference to the accompanying drawings. It is to be noted that substantially the same members are denoted by the same reference numerals in the drawings.

### First Embodiment

FIG. 1 is a cross-sectional view schematically illustrating the structure of an organic electroluminescent element according to the first embodiment of the present invention. This organic electroluminescent element has, on a base material 101, a stacked structure of a positive electrode 102, an organic light-emitting layer 103, an electron injecting layer 104, a laminated negative electrode (lower negative electrode) 206a, and a laminated negative electrode (upper negative electrode) 206b. In this organic electroluminescent element, voltage is applied between the positive electrode 102 and the laminated negative electrode (lower negative electrode) 206a and laminated negative electrode (upper negative electrode) 206b to inject holes from the positive electrode 102 into the organic light-emitting layer 103, and to inject electrons from the laminated negative electrode (upper negative electrode) 206b through the electron injecting layer 104 into the organic light-emitting layer 103. The two types of carriers are moved as excitons through the organic light-emitting layer 103, and recombined in the organic light-emitting layer 103 to produce luminescence.

In FIG. 1, the laminated negative electrode (lower negative electrode) 206a and the laminated negative electrode (upper negative electrode) 206b constitute a negative electrode of ITO films stacked as transparent conductive films, which is composed of two layers having different specific resistances from each other. The laminated negative electrode (lower negative electrode) 206a is deposited as having a specific resistance higher than the specific resistance of laminated negative electrode (upper negative electrode) 206b, and the laminated negative electrode (upper negative electrode) 206b is stacked on the laminated negative electrode (lower negative electrode) 206a to form a negative electrode of two-layer structure. In this the first embodiment, the laminated negative electrode (lower negative electrode) 206a has a specific resistance of 3×10⁻³ Ω·cm and a film thickness of 10 nm, whereas the laminated negative electrode (upper negative electrode) 206b has a specific resistance of 3×10⁻⁴ Ω·cm and a film thickness of 90 nm.

In this configuration, the laminated negative electrode (lower negative electrode) 206a having higher specific resistance causes no deposition damage to the organic light-emitting layer 103 during the deposition. Furthermore, during the deposition of the laminated negative electrode (upper negative electrode) 206b having lower specific resistance, the laminated negative electrode (lower negative electrode) 206a serves as a barrier layer against deposition damage to the organic light-emitting layer 103. As a result, even while improving the luminous efficiency, the laminated negative electrode (upper negative electrode) 206b having lower specific resistance suppresses the voltage drop in a horizontal direction, thereby making it possible to keep the driving voltage low.

As described above, according to this configuration, the laminated negative electrode (lower negative electrode) 206a composed of an ITO film is stacked on the laminated negative electrode (upper negative electrode) 206b composed of another ITO film which is different only in resistance value, thereby allowing the driving voltage to be kept low due to the lower specific resistance of the laminated negative electrode (upper negative electrode) 206b, even while improving the luminous efficiency.

A method for manufacturing the organic electroluminescent element shown in FIG. 1 will be described below.

a) The positive electrode 102 is obtained through deposition of a metal having a high reflectivity by a method such as sputtering. The metal having a high reflectivity can be selected from metals such as aluminum, molybdenum, and silver, and alloys thereof. The positive electrode 102 is subjected, after the deposition, to patterning by methods such as lithography and etching.

b) Next, the organic light-emitting layer 103 is typically composed of a hole transporting layer, a hole injecting layer, a light-emitting layer, etc. Deposition method for the respective layers constituting the organic light-emitting layer 103 may be selected from vapor deposition, spin coating, ink jet and the like. These deposition method is selected depending on the types, etc. of the layers constituting the organic light-emitting layer 103. In any of these methods, patterning is required, and in many cases, etching or the like is not carried out.

c) Further, alkaline-earth metals and salts thereof, and mixtures of alkaline-earth metals with organic matters can be used for the electron injecting layer 104. In addition, the electron injecting layer 104 can be deposited by a vapor deposition method.

d) A transparent conductive film or a semi-transparent conductive film is used for the laminated negative electrode (lower negative electrode) 206a and the laminated negative electrode (upper negative electrode) 206b in the case of a top-emission type element. As the material, a conductive oxide is used such as ITO, IZO, AZO, or GZO. The deposition method can include sputtering, ion plating, vapor deposition and the like. Furthermore, for example, depositing the laminated negative electrode (lower negative electrode) 206a and the laminated negative electrode (upper negative electrode) 206b by varying the composition between the laminated negative electrode (lower negative electrode) 206a and the laminated negative electrode (upper negative electrode) 206b each other, such that the laminated negative electrode (lower negative electrode) 206a and the laminated negative electrode (upper negative electrode) 206b have different specific resistances from each other. Alternatively, the inclusion of an additive for changing specific resistance can make the respective specific resistances of the laminated negative electrode (lower negative electrode) 206a and the laminated negative electrode (upper negative electrode) 206b which are different from each other. In addition, the specific resistances can be changed by changing the deposition conditions. For example, the oxygen flow rate changed during deposition as described later can change the content of oxygen contained in each laminated negative electrode, and thus change the specific resistances.

e) Furthermore, the organic light-emitting layer 103 and the electron injecting layer 104 are often unstable to oxygen and water in the atmosphere. Therefore, can sealing may be carried out in such a way that the organic electroluminescent element is covered with glass and subjected to sealing with a resin, or film sealing may be carried out in such a way that the organic electroluminescent element is coated with a passivation film such as SiN, SiON, or SiO₂. Thus, the ingress of oxygen and water from the atmosphere can be prevented to prevent the organic electroluminescent element from being deteriorated.

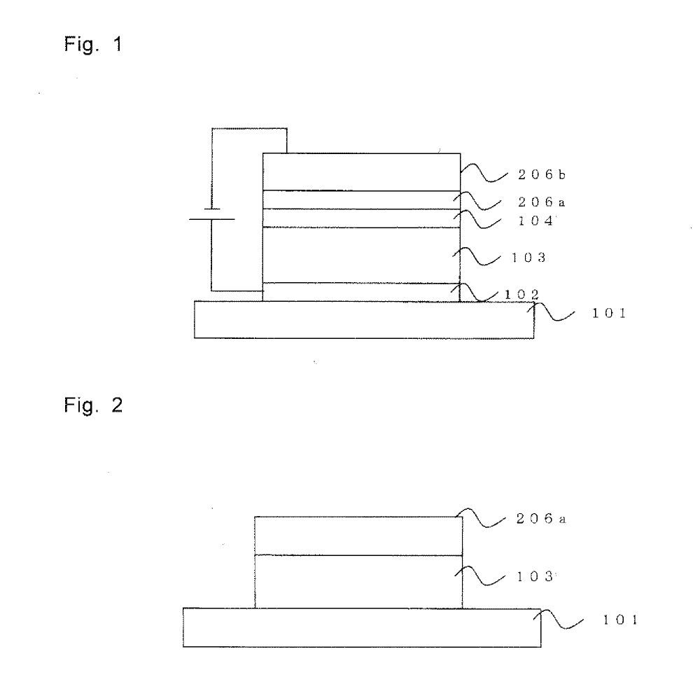

Next, the advantageous effects of the first embodiment will be described with reference to FIGS. 2, 3, and 4. FIG. 2 is a cross-sectional view schematically illustrating a test structure for examining the effect of the specific resistance value of the laminated negative electrode (lower negative electrode) 206a on the PL quantum efficiency in connection with FIG. 1.

It is to be noted that the PL quantum efficiency (which may be referred to as “PL luminous efficiency”) refers to the ratio of emitted light energy to injected light energy.

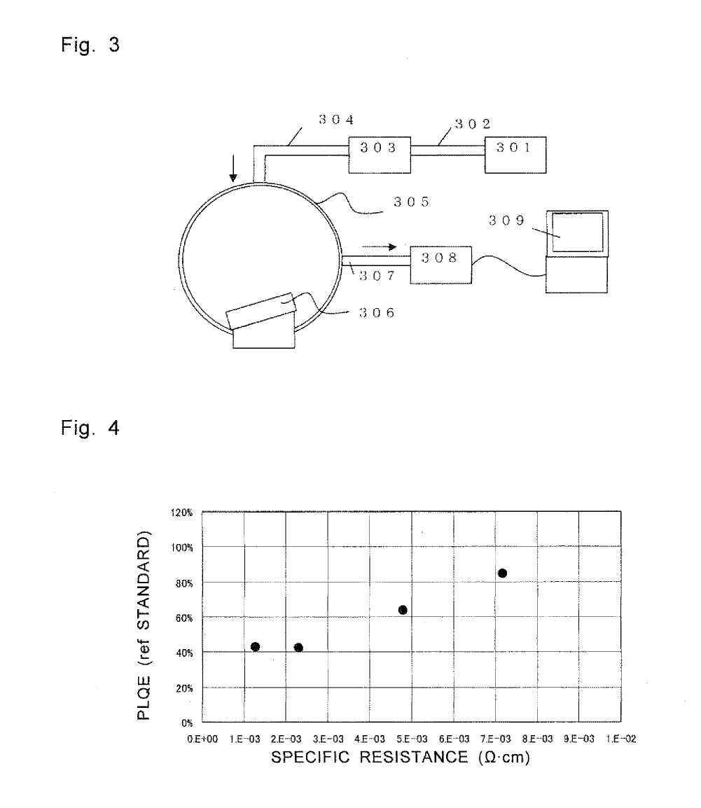

FIG. 3 is a schematic view illustrating a measurement system for measuring the change in PL quantum efficiency in the case of changing the specific resistance of the laminated negative electrode (lower negative electrode) 206a in FIG. 2. In FIG. 3, light of waves guided from a light source 301 via an optical cable 302 is turned into monochromatic light with a desired wavelength in a wavelength-tunable monochromator 303, and then guided by an optical cable 304 into an integrating sphere 305. The sample 306 shown in FIG. 2 is placed in the integrating sphere 305, the organic light-emitting layer of the sample 306 is irradiated with the monochromatic light to produce PL luminescence, and the PL luminescence is measured by a detector 308, and subjected to counting by a personal computer 309, The PL quantum efficiency is calculated by obtaining the ratio of the number of photons of the PL luminescence to the number of photons of incident light falling on the integrating sphere 305. It is necessary to cancel light absorption at the negative electrode, because the incident light passes through the negative electrode to reach the organic light-emitting layer. Thus, the PL quantum efficiency is calculated in such a way that the number of photons absorbed by the negative electrode is subtracted from the number of incident photons. Furthermore, the value of the obtained internal quantum efficiency is normalized so that a sample with no negative electrode deposited has a PL quantum efficiency of 100%.

FIG. 4 shows the results obtained in the way described above, with the horizontal axis for the specific resistance of the laminated negative electrode (lower negative electrode) 206a and the vertical axis for a normalized PL quantum efficiency. Referring to FIG. 4, it is determined that the PL quantum efficiency is increased as the specific resistance of the negative electrode is increased. This is believed to be because the deposition of the ITO film having higher specific resistance reduces deposition damage to the organic light-emitting layer. FIG. 4 shows that the effect of improvement in PL quantum efficiency is produced at 1×10⁻³ Ω·cm or more, and the specific resistance of the laminated negative electrode (lower negative electrode) 206a is thus desirably adjusted to this value or more, and in particular, 5×10⁻³ Ω·cm or more preferably, at which the effect is remarkable in FIG. 4.

In order not to increase the driving voltage significantly, the thickness of the laminated negative electrode (lower negative electrode) 206a is adjusted in the range of 100 nm to 1 nm with respect to the preferable specific resistance 1×10⁻³ to 1×10⁻¹ Ω·cm mentioned above, thereby allowing the resistance value in the thickness direction to be kept constant. In this case, when the thickness is excessively thinner than 1 nm, there is a possibility that the in-plane uniformity in deposition may be degraded excessively. Thus, it is considered necessary that the thickness is 1 nm or more.

While the specific resistance of the laminated negative electrode (upper negative electrode) 206b is preferably small as much as possible, the specific resistance of ITO as the most frequently used transparent conductive film has a limit on the order of 1×10⁻⁴ Ω·cm. Furthermore, in order to perform a conductive function in the in-plane direction of the film as a negative electrode, the sheet resistance measured for the laminated negative electrode (upper negative electrode) 206b itself desirably meets 100 Ω/□ or less.

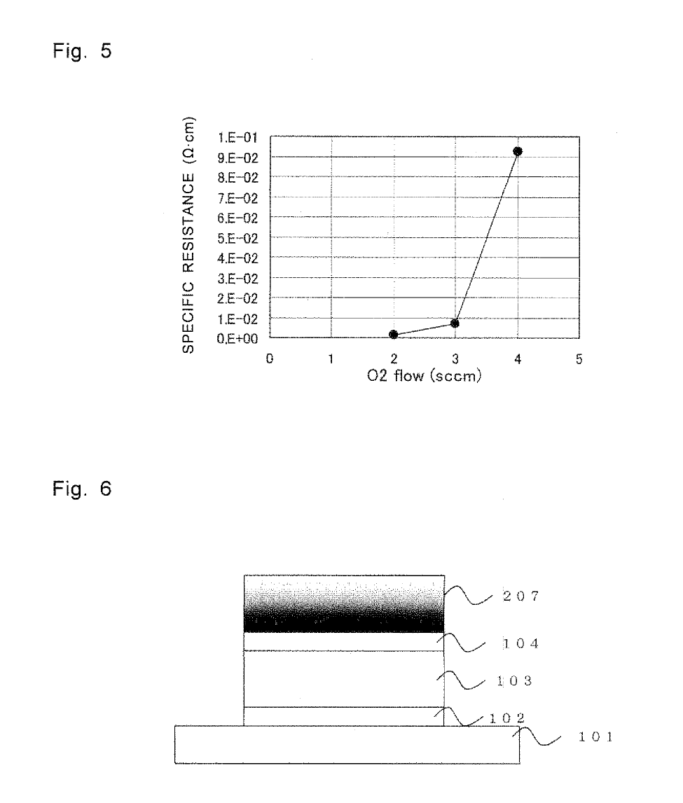

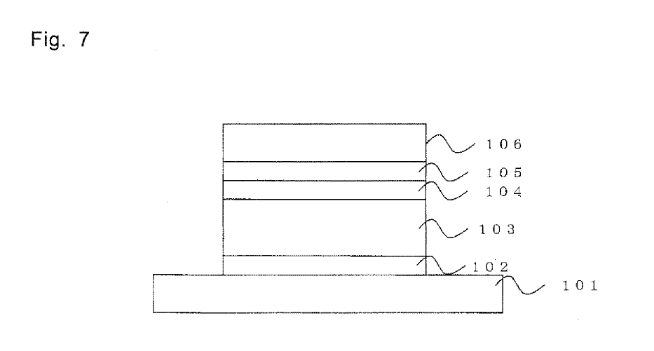

FIG. 5 is a diagram showing the variation in the specific resistance of an ITO film deposited for a thickness of 100 nm, while changing the oxygen introduction amount in the case of sputtering deposition of an ITO film for the laminated negative electrode. From FIG. 5, it is determined that the adjustment of the oxygen flow rate during the deposition makes it possible to adjust the specific resistance. Further, when the oxygen flow rate is further decreased, the specific resistance shows a minimal value, and when the further decreased oxygen flow rate is further decreased, the specific resistance is increased reversely, while the transparency is decreased to be opaque.

It is to be noted that while the case of two layers has been described as the laminated negative electrode in this the first embodiment, multiple layers of three or more layers may be adopted. For example, as long as, among the three or more layers, the laminated negative layer closest to the organic light-emitting layer has specific resistance higher than the specific resistance of the second closest layer, it is believed that at least the effect of improvement in luminous efficiency is produced.

In addition, while the case of using ITO as the negative electrode material has been described in this first embodiment, the negative electrode material is not limited to ITO. The specific resistance is important for producing the effect of improvement in luminous efficiency, it is thus believed that similar effects are also produced in the case of IZO, GZO, AZO, etc. in addition to ITO, as the negative electrode material.

In addition, while the typical structure has been described as the structure of the organic electroluminescent element in this first embodiment, it is obvious that a similar effect is produced as long as a transparent conductive film is mainly used as the negative electrode in the structure, and for example, a structure including no electron injecting layer may be adopted, or a conductive protective layer (barrier layer) may be located on the electron injecting layer.

### Second Embodiment

FIG. 6 illustrates the structure of an organic electroluminescent element according to the second embodiment of the present invention. In FIG. 6, the same reference numerals are used for the same components as those in FIG. 1, and descriptions of the components will be omitted. Referring to FIG. 6, a negative electrode 207 is composed of an ITO film, which has a section at which the specific resistance continuously varies along a direction perpendicular to the surface of the negative electrode. Thus, the specific resistance on the electron injecting layer 104 side of the negative electrode 207 is higher; on the other hand, the specific resistance on the top of the negative electrode 207 is lower. While the element structure described in the first embodiment has the negative electrode composed of separate multiple layers, the multiple layers having different specific resistance each other, a similar effect can be produced by continuously varying the specific resistance of the negative electrode along the direction perpendicular to the surface of the negative electrode as in this second embodiment.

Methods for manufacturing the negative electrode in the organic electroluminescent element according to this second embodiment include sputtering deposition of ITO. In this case, the oxygen flow rate can be increased to form an ITO film having higher specific resistance in the initial stage of the deposition, and the oxygen flow rate can be decreased gradually to form an ITO film having lower specific resistance on the upper side. In this regard, for how to vary the specific resistance, it is not always necessary to vary the relationship between the depth and the specific resistance in a linear manner over all of the region. For example, the specific resistance is preferably decreased as much as possible in the region other than the region for improving the luminous efficiency, because the driving voltage is not increased.

In addition, it is considered preferable from the result in FIG. 4 that the specific resistance on the lower side (the electron injecting layer 104 side) of the negative electrode 207 has a value within the range of 1×10⁻³ to 1×10⁻¹ Ω·cm, and in particular, 5×10⁻³ or more, for the formation of an internal electric field for keeping out electrons. While the specific resistance is preferably low as much as possible on the upper side of the negative electrode 207, ITO as the most frequently used transparent conductive film has a limit on the order of 1×10⁻⁴ Ω·cm. Furthermore, in order to perform a function as the negative electrode, the sheet resistance measured from the upper side desirably meets 100 Ω/□ or less. In addition, it is considered preferable that the thickness from the lower side with a specific resistance of 1×10⁻³ Ω·cm or more through the gradually decreased specific resistance down to 1×10⁻³ Ω·cm or less is 100 nm or less because the excessively increased thickness causes an increase in driving voltage, and it is considered necessary that the thickness is 1 nm or more because the thickness excessively thinner than 1 nm fails to produce an effect as a film.

While the case of using an ITO film as the negative electrode material has been also described as an example in this second embodiment, it comes near to stating the obvious that similar effects are also produced in the case of using other conductive materials for transparent oxide films, such as IZO, AZO, and GZO, as the negative electrode material.

In addition, on the subject of the present invention, while the typical structures have been described as the structure of the organic electroluminescent element in each of the embodiments, it is obvious that a similar effect is produced as long as a transparent conductive film is mainly used as the negative electrode in the structure. For example, a structure including no electron injecting layer may be adopted, or a conductive protective layer (barrier layer) may be provided on the electron injecting layer.

The organic electroluminescent element according to the present invention is a top-emission type element which has a high luminous efficiency and a low driving voltage while using a transparent conductive film such as ITO. Therefore, the present invention can be applied to uses of two-sided light extraction structures such as organic electroluminescent elements.

### EXPLANATION OF REFERENCE NUMERALS

101 substrate
102 positive electrode
103 organic light-emitting layer
104 electron injecting layer
105 conductive protective film
106 negative electrode
206a laminated negative electrode (lower negative electrode)
206b laminated negative electrode (upper negative electrode)
207 negative electrode
301 light source
302 optical cable
303 wavelength-tunable monochromator
304 optical cable
305 integrating sphere
306 sample
307 optical cable
308 detector
309 personal computer

1. An organic electroluminescent element comprising:
a substrate; and
a positive electrode, an organic light-emitting layer, and a laminated negative electrode of two or more layers including a lower negative electrode and an upper negative electrode, the positive electrode, organic light-emitting layer, and laminated negative electrode sequentially provided on the substrate from the substrate side, wherein the lower negative electrode and the upper negative electrode have different specific resistances from each other,
wherein the lower negative electrode and the upper negative electrode include any one of ITO, IZO, GZO, and AZO as a main constituent of, and
the lower negative electrode is provided closer to the organic light-emitting layer than the upper negative electrode, and the lower negative electrode has a specific resistance higher than the specific resistance of the upper negative electrode adjacent to the lower negative electrode.

2. The organic electroluminescent element according to claim 1, wherein the lower negative electrode provided closer to the organic light-emitting layer has a specific resistance within a range of 1×10⁻³ to 1×10⁻¹ Ω·cm.

3. An organic electroluminescent element comprising:
a substrate; and
a positive electrode, an organic light-emitting layer, and a negative electrode sequentially provided on the substrate from the substrate side,
wherein the negative electrode includes, as its main constituent, any one of ITO, IZO, GZO, and AZO, and specific resistance of the negative electrode at an interface on the organic light-emitting layer side is higher than specific resistance of the negative electrode at an upper side opposed to the organic light-emitting layer, and
the negative electrode includes a section at which the specific resistance continuously varies along a direction perpendicular to the surface of the negative electrode.

4. A method for manufacturing an organic electroluminescent element having a positive electrode, an organic light-emitting layer, and a laminated negative electrode of two or more layers, sequentially deposited on a substrate, the method comprising:
depositing a positive electrode and an organic light-emitting layer sequentially on a substrate; and
depositing a laminated negative electrode of two or more layers on the organic light-emitting layer,
wherein in the step of depositing the laminated negative electrode, any one of ITO, IZO, GZO, and AZO is selected as a main constituent of each layer of the laminated negative electrode, and
the composition for depositing the laminated negative electrode is changed at the point of depositing the layer adjacent to the layer closest to the organic light-emitting layer, as compared to at the point of depositing the layer closest to the organic light-emitting layer, so that the specific resistance of the layer closest to the organic light-emitting layer is made higher than the specific resistance of the layer adjacent to the closest layer of the laminated negative electrode.

5. A method for manufacturing an organic electroluminescent element having a positive electrode, an organic light-emitting layer, and a negative electrode sequentially deposited on a substrate, the method comprising:
depositing a positive electrode and an organic light-emitting layer sequentially on a substrate; and
depositing a negative electrode on the organic light-emitting layer,
wherein in the step of depositing the negative electrode, any one of ITO, IZO, GZO, and AZO is selected as a main constituent of the negative electrode, and
the negative electrode is deposited by continuously varying the composition along a direction perpendicular to the surface of the negative electrode, so that the specific resistance at an interface of the negative electrode on the organic light-emitting layer side is made higher than the specific resistance at an interface thereof on the upper side opposite to the organic light-emitting layer.
